(19) United States
(12) Patent Application Publication
(10) Pub. No.: US 2026/0100703 A1
(43) Pub. Date: Apr. 9, 2026

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventor: Meng-Sheng Chang, Hsinchu City (TW)

(73) Assignee: Taiwan Semiconductor Manufacturing Company, Ltd., Hsinchu (TW)

(21) Appl. No.: 19/054,173

(22) Filed: Feb. 14, 2025

Related U.S. Application Data
(60) Provisional application No. 63/703,354, filed on Oct. 4, 2024.

(51) Int. Cl. H03K 19/00; G06F 1/3296; H01L 23/528; H03K 19/0185

(52) U.S. Cl. CPC H03K 19/0016; G06F 1/3296; H03K 19/018521; H10W 20/427

(57) ABSTRACT

An integrated circuit comprises a plurality of semiconductor dies, a power network, and a power control circuit. The plurality of semiconductor dies can be disposed on a single semiconductor substrate. Each of the plurality of semiconductor dies may comprise a plurality of operative modules. A plurality of power switches can be coupled to the plurality of operative modules, respectively. The power network can be disposed with respect to the plurality of semiconductor dies. The power control circuit can be configured to: receive a first signal indicating one or more operative modules of at least one of the plurality of semiconductor dies have failed; and based on the first signal, send a second signal to the corresponding power switches coupled to the one or more operative modules, respectively, so as to disconnect the supply voltage from being provided to the one or more operative modules.

### CROSS-REFERENCE TO RELATED APPLICATION

This application claims priority to and the benefit of U.S. Provisional Application No. 63/703,354, filed Oct. 4, 2024, entitled “LOW POWER AI SYSTEM,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic diagram of an integrated circuit, in accordance with some embodiments.

FIG. 2 illustrates an example schematic diagram of a power control circuit of the integrated circuit of FIG. 1, in accordance with some embodiments.

FIG. 3 illustrates an example schematic diagram of an integrated circuit and example waveforms of various signals while operating the integrated circuit, in accordance with some embodiments.

FIG. 4 illustrates an example schematic diagram of a power switch of the integrated circuit of FIG. 1, in accordance with some embodiments.

FIG. 5 illustrates an example schematic diagram of a power switch of the integrated circuit of FIG. 1, in accordance with some embodiments.

FIG. 6 illustrates an example schematic diagram of a power switch of the integrated circuit of FIG. 1, in accordance with some embodiments.

FIG. 7 illustrates an example schematic diagram of a level shifter of the power switch of FIG. 6, in accordance with some embodiments.

FIG. 8 illustrates an example schematic diagram of a power switch of the integrated circuit of FIG. 1, in accordance with some embodiments.

FIG. 9 illustrates example waveforms of various signals while operating the power switch of FIG. 8, in accordance with some embodiments.

FIG. 10 illustrates an example flow chart for testing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some integrated circuit architectures, all dies and modules can be connected to a single power source. This design simplicity facilitates power distribution but introduces a significant vulnerability: failure in any of the dies or modules can lead to anomalous power consumption. When a component/die/module fails, it often draws excessive power, which paradoxically decreases overall computing power due to inefficient resource allocation and increased thermal load. Consequently, this results in a system that not only consumes more power but also delivers lower performance, undermining the efficiency and effectiveness of the integrated circuit in critical applications.

The present disclosure introduces a novel approach to power management in low power artificial intelligence systems by integrating an embedded power header in each module, ensuring decentralized and autonomous power control. This design is critical for enhancing the system's overall energy efficiency. By allowing each module to regulate its own power supply, the system minimizes unnecessary power consumption and reduces the risk of power-related failures that can occur when a single power source feeds all components/modules/dies on a single substrate/wafer. The embedded power header of each module optimizes computing power by ensuring that each module operates within its optimal power range, thereby maximizing performance and extending the lifespan of the system components. This architecture not only provides a low power solution but also significantly boosts computational efficiency.

The present disclosure provides various embodiments of an integrated circuit comprising a plurality of semiconductor dies, a power network, and a power control circuit. The plurality of semiconductor dies can be disposed on a single semiconductor substrate. Each of the plurality of semiconductor dies may comprise a plurality of operative modules. A plurality of power switches can be coupled to the plurality of operative modules, respectively. The power network can be disposed with respect to the plurality of semiconductor dies and can be configured to provide a supply voltage to each of the plurality of semiconductor dies. The power control circuit can be disposed on the semiconductor substrate. The power control circuit can be configured to: receive a first signal indicating one or more operative modules of at least one of the plurality of semiconductor dies have failed; and based on the first signal, send a second signal to the corresponding power switches coupled to the one or more operative modules, respectively, so as to disconnect the supply voltage from being provided to the one or more operative modules. The proposed integrated circuit offers a low-power solution and significantly enhances computational efficiency in artificial intelligence computing.

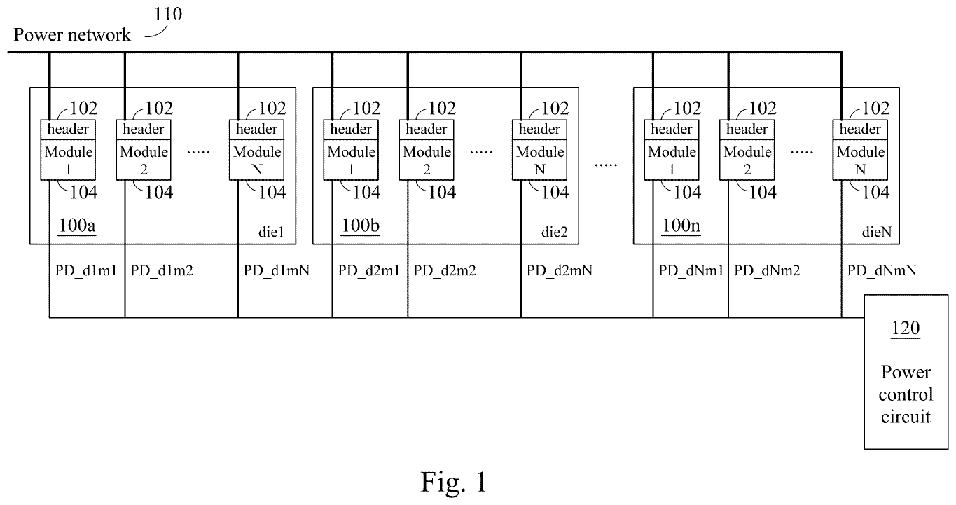

FIG. 1 illustrates an example schematic diagram of an integrated circuit 100, in accordance with some embodiments. The integrated circuit 100 may comprise a plurality of semiconductor dies 100a, 100b, 100n, a power network 110, and a power control circuit 120. In some embodiments, the plurality of semiconductor dies 100a, 100b, 100n can be disposed on a single semiconductor substrate (e.g., a wafer). The semiconductor substrate can serve as a foundation for a circuitry layer, where active microelectronic devices are constructed. The circuitry layer typically defines one or more surfaces on each die, onto which circuits and various microelectronic devices are fabricated using lithography systems. The semiconductor substrate is preferably made of silicon, but it may also be composed of or include other suitable materials such as silicon dioxide, aluminum oxide, sapphire, germanium, gallium arsenide, an alloy of silicon and germanium, indium phosphide, and the like. In its basic form, the substrate may be a virgin wafer. Additionally, the substrate may incorporate one or more layers of materials like photoresist, dielectric, and conductive materials. Photoresist, a light-sensitive material used in lithography, can be either positive or negative type. The semiconductor substrate, typically circular in shape, is available in various diameters including 100 mm, 150 mm, 200 mm, 300 mm, and 450 mm, facilitating the fabrication of integrated circuits.

In some embodiments, each of the plurality of semiconductor dies (e.g., die1 100a, die2 100b, . . . , dieN 100n) may comprise a plurality of operative modules 104 (e.g., Module 1, Module 2, Module 3, . . . , Module N). In some embodiments, the operative modules 104 of each semiconductor die can be identical to one another. In some embodiments, each of the operative modules 104 can serve as a computing unit for artificial intelligence. In some embodiments, each of the plurality of operative modules 104 may include one of the following: a natural language processing (NLP) module, a computer vision module, a speech recognition module, a recommendation system module, a predictive analytics module, an autonomous navigation module, an anomaly detection module, an emotion detection module, a generative model module, a knowledge graph module, an optical character recognition module, a data cleaning module, a dynamic pricing module, a pose estimation module, or a time series analytics module. In some embodiments, the integrated circuit may include several specialized modules tailored for various artificial intelligence tasks. The natural language processing (NLP) module processes human language to perform tasks such as translation and sentiment analysis. The computer vision module interprets visual data, enabling image recognition and object detection. The speech recognition module converts spoken language into text for voice command functionality, while the recommendation system module personalizes suggestions for users on platforms such as online shopping. The predictive analytics module uses historical data to forecast future events, useful in fields like finance and healthcare. The autonomous navigation module enables robots and vehicles to navigate without human input, using technologies like GPS and lidar. The anomaly detection module identifies unusual data patterns, critical in areas like fraud detection. The emotion detection module recognizes human emotions from facial expressions or voice tones, enhancing customer service applications. The generative model module creates new data instances, such as synthetic images or music. The knowledge graph module organizes information in logical relationships, aiding in semantic search and decision support. The optical character recognition (OCR) module converts documents into editable formats. The data cleaning module corrects errors in datasets to ensure data quality. The dynamic pricing module adjusts prices based on market conditions, commonly used in e-commerce. The pose estimation module determines the position of objects in images, utilized in augmented reality, and the time series analytics module analyzes sequential data points for forecasting in finance and weather prediction. Each module is equipped with specific algorithms to efficiently handle its designated tasks within the AI system.

In some embodiments, a plurality of inter-die connections can be formed between the plurality of semiconductor dies (e.g., die1 100a, die2 100b, . . . , dieN 100n) to establish communication. The plurality of semiconductor dies 100a, 100b, 100n may be directly connected with one or more inter-die connections or, at a minimum, indirectly connected via intermediate inter-die connections established between one or more semiconductor dies. Such configuration(s), therefore, enabling faster communications and data processing between die when compared, at least, to communications between die not maintained on a same substrate (e.g., a same wafer). Each of the plurality of semiconductor dies 100a, 100b, 100n remain on the single substrate and are not cut from the substrate into individual die for separate packaging into an individual computer chip. Rather, at formation, only excess die (e.g., die that are not provided with circuitry or inactive die) along a periphery of the substrate are preferably removed from the substrate and the remaining portions of the substrate having the plurality of semiconductor dies 100a, 100b, 100n (e.g., active die) may form a predetermined shape (e.g., a rectangular shape) with the substrate. The resultant substrate after being reduced to shed excess die and potentially following one or more additional refinement or IC production processes may then be packaged onto a board (e.g., a printed circuit board (PCB) or an organic substrate).

In some embodiments, a plurality of power switches 102 can be coupled to the plurality of operative modules 104, respectively. In some embodiments, the power switches 102 can be configured to selectively decouple a voltage carried through the power network 110 from a corresponding operative module based on a first signal indicating that the corresponding operative module has failed. In some embodiments, the voltage may include a supply voltage (VDD) or a ground voltage (VSS). In some embodiments, the power switches 102 may comprise at least one of: a header or a footer. In electronic circuit design, particularly within integrated circuits, “header” and “footer” may refer to specific configurations of transistors used for controlling power distribution. A header, often called a “pull-up” transistor, can be typically an n-type MOSFET and can be used to connect a circuit node to a positive voltage supply (VDD). Positioned at the top of a circuit layout, the header transistor may serve to elevate the voltage to the supply level when activated, allowing current to flow through the circuit. Conversely, a footer, known as a “pull-down” transistor, usually a p-type MOSFET, can be placed at the bottom of the layout and connects a circuit node to the ground or a lower voltage level (VSS). This footer transistor pulls the voltage down to ground level under specific conditions, completing the path for current to exit the circuit. In some embodiments, at least one of the plurality of power switches 102 can be configured to selectively decouple a voltage carried through a power network 110 from the corresponding operative module 104 based on a first signal indicating that the corresponding operative module has failed.

The power switch (e.g., header) feature in the circuit design serves as a critical control element, functioning to selectively permit or restrict electrical flow based on operational requirements. This component can be configured using various transistor types, including all NMOS, all PMOS, or a combination of PMOS and NMOS, depending on the specific requirements of the application. The versatility of the header's composition allows it to adapt to different power handling and switching characteristics, making it suitable for a range of electronic environments. In certain embodiments, the header incorporates an embedded level shifter, a vital addition that enables the conversion of low voltage signals to high voltage outputs. This feature is particularly beneficial in high voltage applications, where maintaining signal integrity at higher operational voltages is crucial. By integrating a level shifter within the header, the circuit ensures that voltage levels are appropriately managed, supporting stable and efficient high-voltage operations.

In some embodiments, each of the plurality of power switches may include: a first inverter configured to receive a first data bit of the second signal and logically invert the first data bit to provide a second data bit; a second inverter configured to receive the second data bit and logically invert the second data bit to provide a third data bit; and a p-type transistor having a source terminal coupled to the power network, a gate terminal configured to receive the third data bit, and a drain terminal coupled to the corresponding operative module.

In some embodiments, each of the plurality of power switches may include: a first inverter configured to receive a first data bit of the second signal and logically invert the first data bit to provide a second data bit; a second inverter configured to receive the second data bit and logically invert the second data bit to provide a third data bit; a first p-type transistor having a source terminal coupled to the power network, a gate terminal configured to receive the third data bit, and a drain terminal; and a second p-type transistor having a source terminal coupled to the drain terminal of the first p-type transistor, a gate terminal configured to receive a half of the supply voltage, and a drain terminal coupled to the corresponding operative module.

In some embodiments, each of the plurality of power switches may include: a first inverter configured to receive a first data bit of the second signal and logically invert the first data bit to provide a second data bit; a second inverter configured to receive the second data bit and logically invert the second data bit to provide a third data bit; a third inverter configured to receive the third data bit and logically invert the third data bit to provide a fourth data bit; a fourth inverter configured to receive the fourth data bit and logically invert the fourth data bit to provide a fifth data bit; a first p-type transistor having a source terminal coupled to the power network, a gate terminal configured to receive the fifth data bit, and a drain terminal coupled to the corresponding operative module; and a second p-type transistor having a source terminal coupled to the power network, a gate terminal configured to receive the third date bit, and a drain terminal coupled to the corresponding operative module. In certain embodiments, a size of the second p-type transistor can be smaller than a size of the first p-type transistor.

In some embodiments, the plurality of semiconductor dies 100a, 100b, 100n can be disposed on a single semiconductor substrate, such as a wafer or a panel. The substrate can serve as a foundation for a circuitry layer, where active microelectronic devices are constructed. The circuitry layer typically defines one or more surfaces on each die, onto which circuits and various microelectronic devices are fabricated using lithography systems. The semiconductor substrate is preferably made of silicon, but it may also be composed of or include other suitable materials such as silicon dioxide, aluminum oxide, sapphire, germanium, gallium arsenide, an alloy of silicon and germanium, indium phosphide, and the like. In its basic form, the substrate may be a virgin wafer. Additionally, the substrate may incorporate one or more layers of materials like photoresist, dielectric, and conductive materials. Photoresist, a light-sensitive material used in lithography, can be either positive or negative type. The semiconductor substrate, typically circular in shape, is available in various diameters including 100 mm, 150 mm, 200 mm, 300 mm, and 450 mm, facilitating the fabrication of integrated circuits.

In some embodiments, the power network 110 can be disposed with respect to the plurality of semiconductor dies 100a, 100b, 100n. The power network 110 can be configured to provide a supply voltage to each of the plurality of semiconductor dies 100a, 100b, 100n. In some embodiments, the power network 110 may comprise a plurality of interconnect structures disposed in one or more metallization layers formed over the semiconductor substrate. These metallization layers may include metals such as copper or aluminum. The primary function of the power network is to provide stable supply voltages to various semiconductor dies on the substrate, ensuring that each module receives the necessary power for its operations if the module meets the operational requirements.

In some embodiments, a power control circuit 120 can be disposed on the semiconductor substrate. The power control circuit 120 can be configured to receive a first signal indicating one or more operative modules of at least one of the plurality of semiconductor dies have failed. Based on the first signal, the power control circuit 120 can be configured to send a second signal to the corresponding power switches coupled to the one or more operative modules, respectively, so as to disconnect the supply voltage from being provided to the one or more operative modules. In some embodiments, the power control circuit 120 can function as a header decoder. The power control circuit 120 may send a signal to disable or disconnect supply voltages to corresponding power switches for a specific module on a given die. For example, if module 1 on die 2 fails, the power control circuit can send a signal to the header of module 1 on die 2, disabling the header and preventing the supply voltage from being delivered. In some embodiments, the first signal may include a first number (N₁) of first data bits. The second signal may include a second number (N₂) of second data bits. In some embodiments, N₂ can be equal to 2^{N}^{₁}. In some embodiments, N₂ can be equal to a total number of the power switches formed on the semiconductor substrate. In some embodiments, the header decoder in the circuit design is crafted to address the needs of multi-module selection within complex systems. It can be designed to accommodate scenarios where more than one module may fail simultaneously, thereby necessitating a decoder that can engage multiple modules concurrently to ensure system stability and functionality.

In some embodiments, the power control circuit 120 may comprise a plurality of first inverters, a plurality of NAND gates, and a plurality of second inverters. Each of the plurality of first inverters can be configured to logically invert a corresponding one of the first data bits to provide N₁ third data bits. Each of the plurality of NAND gates can be configured to input a corresponding pair of the third data bits to provide N₂ fourth data bits. Each of the plurality of second inverters can be configured to logically invert a corresponding one of the fourth data bits to provide a corresponding one of the second data bits.

The method for testing whether a module has failed includes several key steps. Initially, all dies and modules within the system are activated for a comprehensive scanning test. This initial step ensures that each component is operational and ready for further diagnostics. During this phase, the current drawn by each module is closely monitored. Deviations in current levels can indicate a potential failure. Specifically, if a module's current does not meet predefined standard requirements, it is flagged as potentially faulty. Once a module is identified as failed, the next step involves the power control circuit. The power control circuit plays a critical role in addressing the failure. The power control circuit adjusts the decoder settings specifically for the faulty modules. By setting the correct decoder address, the power control circuit effectively controls the system or specific elements like the headers associated with the failed modules. The action taken includes disabling the headers of the failed modules, which prevents further supply of voltage to the malfunctioning unit. This isolation helps prevent extra power consumption and maintains the overall stability and functionality of the circuit.

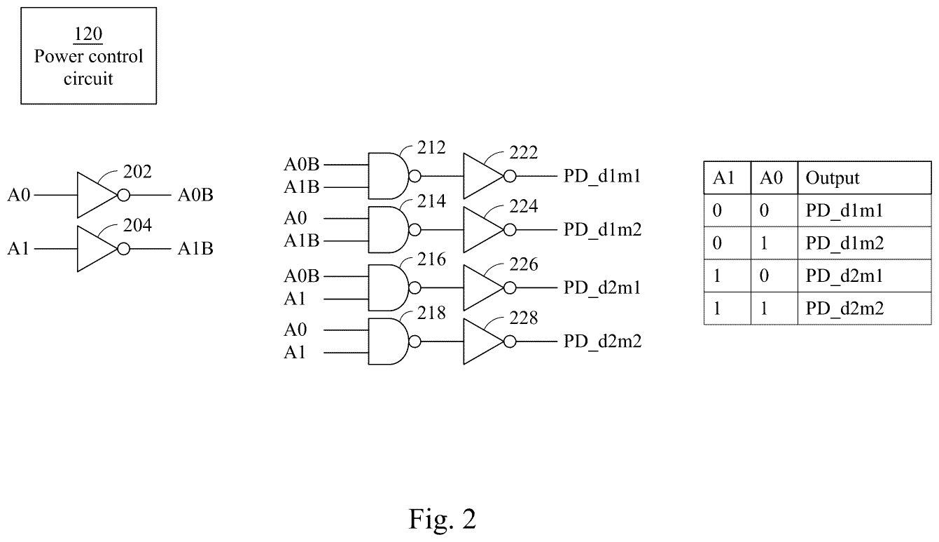

FIG. 2 illustrates an example schematic diagram of a power control circuit 120 of the integrated circuit of FIG. 1, in accordance with some embodiments. FIG. 2 provides a detailed illustration of a system configuration comprising two dies, each of the dies including two modules. The power control circuit 120 may utilize two control pins which are integral to the operation of the integrated circuit. These control pins facilitate the generation of four distinct signals: PD_d1m1, PD_d1m2, PD_d2m1, and PD_d2m2. Each signal corresponds to a specific module on each die, effectively controlling the power disable function. In some embodiments, the power control circuit 120 can function as a header decoder. The power control circuit 120 may send a signal to disable or disconnect supply voltages to corresponding power switches for a specific module on a given die.

In some embodiments, the power control circuit 120 may comprise a plurality of first inverters 202, 204, a plurality of NAND gates 212, 214, 216, 218, and a plurality of second inverters 222, 224, 226, 228. Each of the plurality of first inverters 202, 204 can be configured to logically invert a corresponding one of the first data bits (e.g., A0, A1) to provide N₁ third data bits (e.g., A0B, A1B). For example, the first inverter 202 may receive an A0 signal and output an inverted A0B signal. Each of the plurality of NAND gates 212, 214, 216, 218 can be configured to input a corresponding pair of the third data bits and the first data bits to provide N₂ fourth data bits. For example, the NAND gate 212 may receive an A0B signal and an A1B signal. The NAND gate 212 may then output a signal referred to as fourth data. Each of the plurality of second inverters 222, 224, 226, 228 can be configured to logically invert a corresponding one of the fourth data bits to provide a corresponding one of the second data bits (e.g., PD_d1m1, PD_d1m2, PD_d2m1, PD_d2m2). For example, the second inverter 222 may receive the fourth data and output a PD_d1m1 signal, indicating that module 1 on die 1 has failed.

The power control circuit 120 can be configured to receive a first signal (e.g., A0, A1). The first signal may indicate one or more operative modules of at least one of the plurality of semiconductor dies have failed. Based on the first signal, the power control circuit 120 can be configured to send a second signal (e.g., PD_d1m1, PD_d1m2, PD_d2m1, PD_d2m2) to the corresponding power switches coupled to the one or more operative modules, respectively, so as to disconnect the supply voltage from being provided to the one or more operative modules. In some embodiments, the first signal may include a first number (N₁) of first data bits (e.g., A0, A1). The second signal may include a second number (N₂) of second data bits (e.g., PD_d1m1, PD_d1m2, PD_d2m1, PD_d2m2). In some embodiments, N₂ can be equal to 2^{N}^{₁}. In some embodiments, N₂ can be equal to a total number of the power switches formed on the semiconductor substrate. When A1=0 and A0=0, the power control circuit 120 may output a signal to disable the header of module 1 on die 1 (e.g., PD_d1m1). When A1=0 and A0=1, the power control circuit 120 may output a signal to disable the header of module 2 on die 1 (e.g., PD_d1m2). When A1=1 and A0=0, the power control circuit 120 may output a signal to disable the header of module 1 on die 2 (e.g., PD_d2m1). When A1=1 and A0=1, the power control circuit 120 may output a signal to disable the header of module 2 on die 2 (e.g., PD_d2m2).

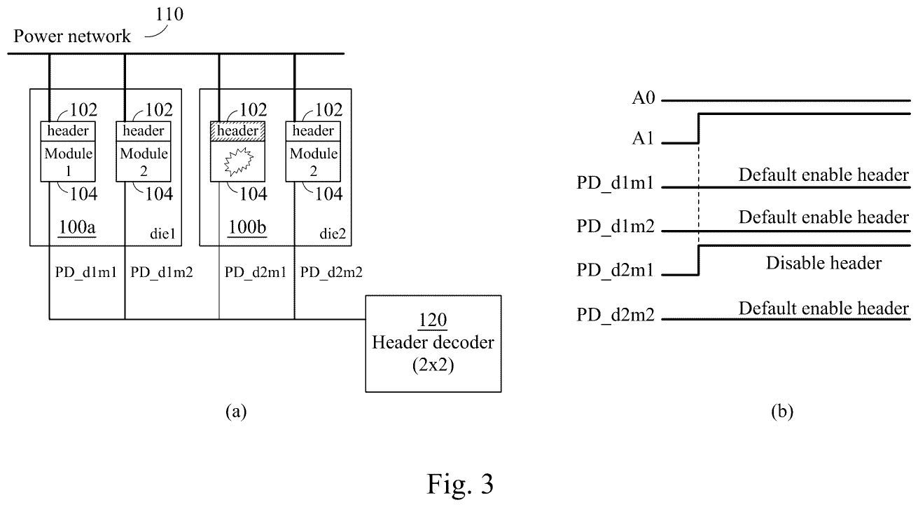

FIG. 3 illustrates an example schematic diagram of an integrated circuit and example waveforms of various signals while operating the integrated circuit, in accordance with some embodiments. FIG. 3 illustrates an example when a module on a die is failed. In some embodiments, if module 1 on die 2 encounters a failure, the power control circuit 120 is capable of swiftly responding by sending a signal, designated as PD_d2m1, directly to the header 102 of module 1 on die 2. This signal effectively disables the header, thereby cutting off the supply voltage from the power network 110 to the failed module.

As depicted in FIG. 3(b), the system is initially configured such that, at the beginning of an operation cycle, all modules' headers are enabled by default. This setup ensures that all modules start from a standard operational state, allowing for consistent performance evaluation and management across the board. However, when module 1 on die 2 is tested and subsequently identified as defective, the control logic within the power control circuit 120 adjusts its response based on this specific condition. The A1 signal is triggered to go high, signifying a problem with the module. Under the conditions where A1=1 and A0=0, the power control circuit 120 then actively outputs the PD_d2m1 signal to immediately disable the header of module 1 on die 2. This fail-safe response not only isolates the malfunctioning module to prevent potential harm but also maintains the stability and efficiency of the remaining system. By implementing such a mechanism, the integrated circuit ensures that operational disruptions are minimized and that module failures do not compromise the integrity of the entire system on the single semiconductor substate.

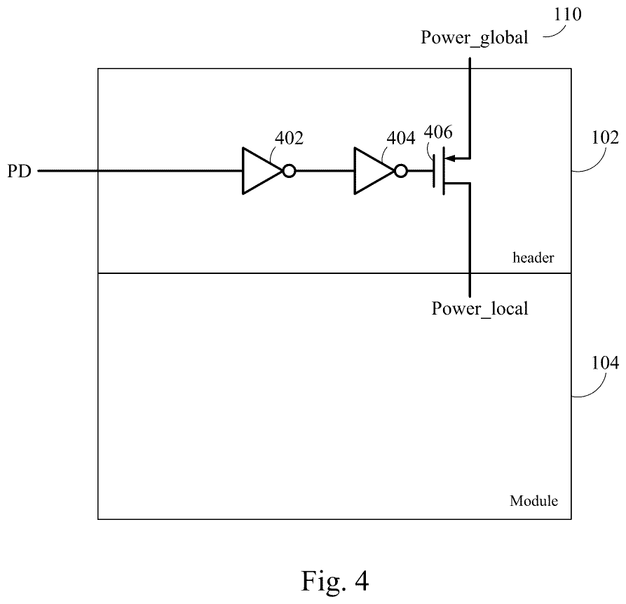

FIG. 4 illustrates an example schematic diagram of a power switch 102 of the integrated circuit 100 of FIG. 1, in accordance with some embodiments. Each of semiconductor dies of the integrated circuit 100 may comprise a plurality of operative modules 104. Each of the operative modules 104 can be coupled to a power switch 102 (e.g., a header or a footer). In some embodiments, the power switches 102 may include a first inverter 402, a second inverter 404, and a p-type transistor 406. The first inverter 402 can be configured to receive a first data bit (e.g., PD) of the second signal and logically invert the first data bit to provide a second data bit. The second inverter 404 can be configured to receive the second data bit and logically invert the second data bit to provide a third data bit. The p-type transistor 406 may have a source terminal coupled to the power network 110, a gate terminal configured to receive the third data bit, and a drain terminal coupled to the corresponding operative module 104. The power switch / power header 102 in the integrated circuit design plays a crucial role in managing the power state of individual modules. Specifically, the power switch 102 operates under a simple yet effective binary signaling mechanism. When the PD signal is set to low (L), power is supplied to the module, effectively turning it on. Conversely, when the PD signal is set to high (H), the power to the module is cut off, resulting in the module being powered off. This binary control allows for precise and efficient management of power distribution across various modules within the single semiconductor substate, ensuring that power is utilized on functional modules, thereby enhancing the overall energy efficiency of the system. The power switch 102 can control what to allow and what to block. This mechanism is particularly valuable in complex electronic systems where optimal power management is crucial to maintaining system stability and reducing energy consumption.

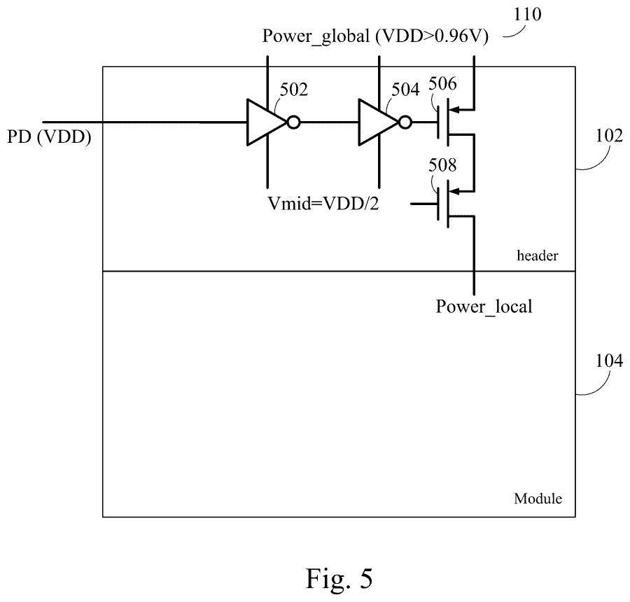

FIG. 5 illustrates an example schematic diagram of a power switch 102 of the integrated circuit of FIG. 1, in accordance with some embodiments. Each of semiconductor dies of the integrated circuit 100 may comprise a plurality of operative modules 104. Each of the operative modules 104 can be coupled to a power switch 102 (e.g., a header or a footer). In some embodiments, the power switches 102 may include a first inverter 502, a second inverter 504, a first p-type transistor 506, and a second p-type transistor 508. The first inverter 502 can be configured to receive a first data bit (e.g., PD) of the second signal and logically invert the first data bit to provide a second data bit. The second inverter 504 can be configured to receive the second data bit and logically invert the second data bit to provide a third data bit. The first p-type transistor 506 may have a source terminal coupled to the power network 110 to receive the supply voltage (e.g., VDD), a gate terminal configured to receive the third data bit, and a drain terminal. The second p-type transistor 508 may have a source terminal coupled to the drain terminal of the first p-type transistor 506, a gate terminal configured to receive a half of the supply voltage (e.g., VDD/2), and a drain terminal coupled to the corresponding operative module 104. The integrated circuit utilizes the power header 102 specifically designed to handle high power applications, where the supply voltage (VDD) exceeds typical device reliability thresholds (e.g., VDD>0.96V). In this configuration, the power header operates using a straightforward control mechanism: setting the power disable (PD) signal to low (L) turns the power on for the module, allowing the module to function under higher power conditions without compromising device reliability. Conversely, setting the PD signal to high (H) turns the power off, ensuring that no power is supplied to the module. This configuration ensures that despite the high power settings, there are no reliability issues with the devices. The design effectively manages the risk of overvoltage damage by enabling precise control over power application, thereby safeguarding the circuit components from potential stress or failure while maintaining optimal performance.

In some embodiments, the power switch 102 can be a multi-stack configuration (e.g., N stack). The power switches 102 may include a plurality of p-type transistors (e.g., N p-type transistors). In this arrangement, each stack can accommodate a different voltage level, allowing for tailored electrical properties per stack. For instance, a configuration with N=2 demonstrates the use of a halved voltage (VDD/2), optimizing the circuit for specific performance requirements or power constraints. In some embodiments, N can be greater than or equal to 1, ensuring a basic threshold for circuit functionality is maintained across all configurations. This multi-stack approach not only allows for greater customization within electronic designs but also improves the efficiency and adaptability of the circuits to various operational demands.

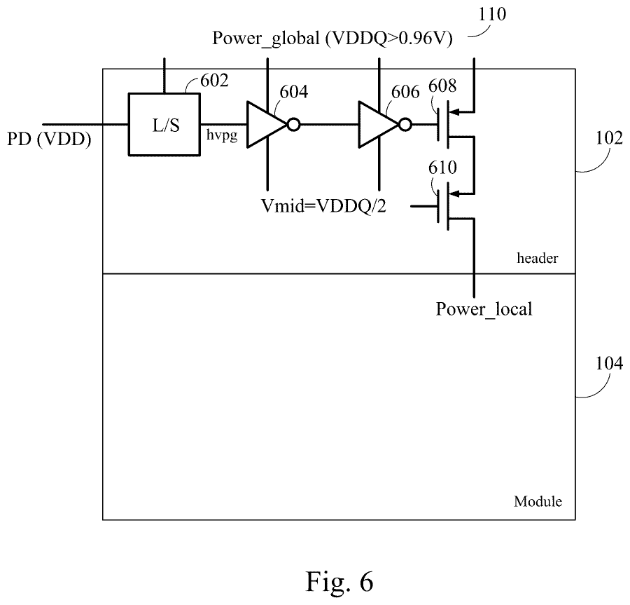

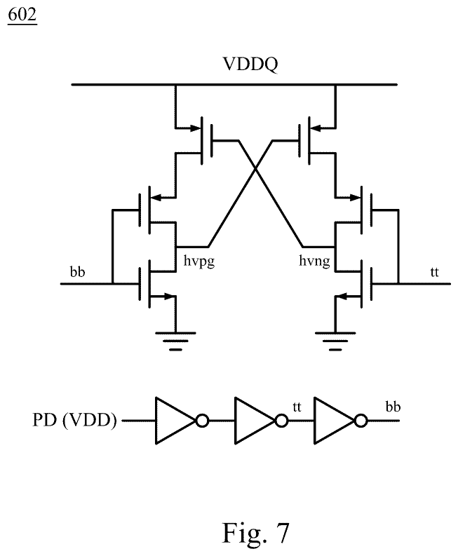

FIG. 6 illustrates an example schematic diagram of a power switch 102 of the integrated circuit of FIG. 1, in accordance with some embodiments. FIG. 7 illustrates an example schematic diagram of a level shifter 602 of the power switch 102 of FIG. 6, in accordance with some embodiments. Each of semiconductor dies of the integrated circuit 100 may comprise a plurality of operative modules 104. Each of the operative modules 104 can be coupled to a power switch 102 (e.g., a header or a footer).

In some embodiments, the power switches 102 may include a level shifter 602, a first inverter 604, a second inverter 606, a first p-type transistor 608, and a second p-type transistor 610. The level shifter 602 may receive a supply voltage VDD and a supply voltage VDDQ (e.g., about >0.96 V). The level shifter 602 can be configured to shift voltage from a first voltage domain to a second voltage domain for the module 104. The first inverter 604 can be configured to receive a first data bit (e.g., hvpg) of the second signal and logically invert the first data bit to provide a second data bit. The second inverter 606 can be configured to receive the second data bit and logically invert the second data bit to provide a third data bit. The first p-type transistor 608 may have a source terminal coupled to the power network 110 to receive the supply voltage (e.g., VDDQ), a gate terminal configured to receive the third data bit, and a drain terminal. The second p-type transistor 610 may have a source terminal coupled to the drain terminal of the first p-type transistor 608, a gate terminal configured to receive a half of the supply voltage (e.g., VDDQ/2), and a drain terminal coupled to the corresponding operative module 104. As illustrated in FIG. 7, the circuit functions as the level shifter 602, converting signals from tt to hvng and from bb to hvpg, for instance. The integrated circuit design features an advanced power header tailored for high-power applications where the supply voltage (VDDQ) exceeds typical device reliability thresholds (e.g., VDDQ>0.96 V). In this setup, the PD signal operates within the VDD control domain, effectively managing the power states of the module. Specifically, when PD is low (L), the module is powered on, and when PD is high (H), the module is powered off, ensuring that high voltage does not compromise device reliability. Moreover, the design incorporates an embedded level shifter 602 within the VDDQ high voltage (HV) domain, termed Power_global, which plays a role in signal conversion. The level shifter 602 translates input signals based on the PD state: when PD=0 (and tt=0, bb=VDD), the output hvpg is 0; conversely, when PD=VDD (and tt=VDD, bb=0), the output hvpg rises to VDDQ. This integration of a level shifter with the power header ensures seamless functionality across different voltage levels, maintaining stability and performance without any reliability issues, despite the high power conditions. The header 102 incorporates the embedded level shifter 602, a vital addition that enables the conversion of low voltage signals to high voltage outputs. This feature is particularly beneficial in high voltage applications, where maintaining signal integrity at higher operational voltages is crucial. By integrating a level shifter within the header, the circuit ensures that voltage levels are appropriately managed, supporting stable and efficient high-voltage operations.

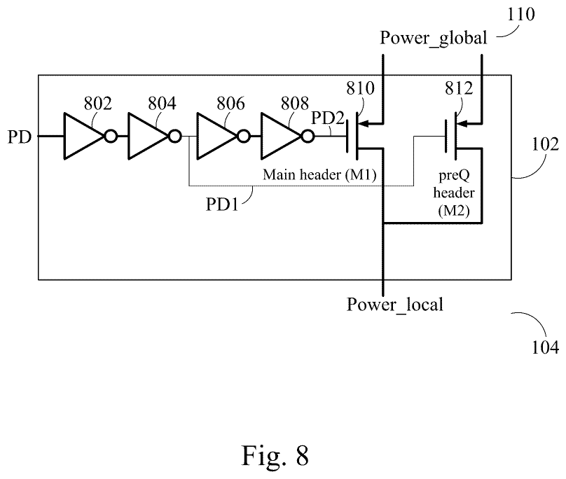

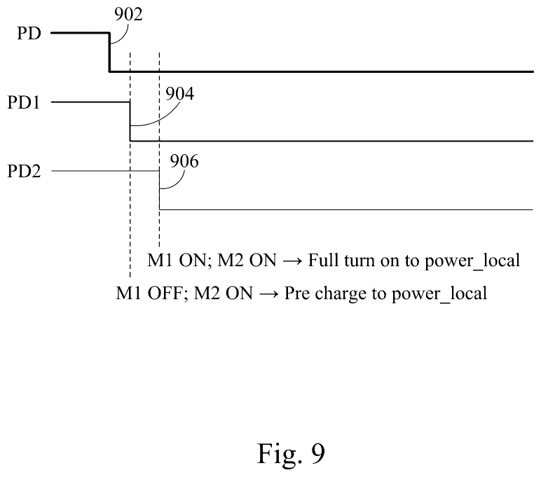

FIG. 8 illustrates an example schematic diagram of a power switch 102 of the integrated circuit of FIG. 1, in accordance with some embodiments. FIG. 9 illustrates example waveforms of various signals while operating the power switch of FIG. 8, in accordance with some embodiments. Each of semiconductor dies of the integrated circuit 100 may comprise a plurality of operative modules 104. Each of the operative modules 104 can be coupled to a power switch 102 (e.g., a header or a footer).

In some embodiments, the power switches 102 may include a first inverter 802, a second inverter 804, a third inverter 806, a fourth inverter 808, a first p-type transistor 810, and a second p-type transistor 812. The first inverter 802 can be configured to receive a first data bit (e.g., PD) of the second signal and logically invert the first data bit to provide a second data bit. The second inverter 804 can be configured to receive the second data bit and logically invert the second data bit to provide a third data bit. The third inverter 806 can be configured to receive the third data bit and logically invert the third data bit to provide a fourth data bit. The fourth inverter 808 can be configured to receive the fourth data bit and logically invert the fourth data bit to provide a fifth data bit. The first p-type transistor 810 may have a source terminal coupled to the power network 110, a gate terminal configured to receive the fifth data bit (e.g., PD2), and a drain terminal coupled to the corresponding operative module 104. The second p-type transistor 812 may have a source terminal coupled to the power network 110, a gate terminal configured to receive the third date bit (e.g., PD1), and a drain terminal coupled to the corresponding operative module 104. In certain embodiments, a size of the second p-type transistor 812 can be smaller than a size of the first p-type transistor 810. In some embodiments, there may include multiple main header (e.g., Mn) and multiple pre-charge header (e.g., Mm) to reduce stress on the system.

In the integrated circuit design, a power header 102 with a pre-charge feature can be employed to enhance the efficiency and responsiveness of the system. The power header 102 may include two main components: the main header (M1) and a smaller, secondary pre-charge header (M2). The size differential between M1 and M2 is strategic; the smaller M2 is designed to pre-charge the circuit, effectively reducing the peak current that occurs during power transitions, which can lead to improved performance and reduced stress on the system. Additionally, this design utilizes two distinct power disable signals, PD1 and PD2, where PD1 operates faster than PD2, as indicated by the timing parameters T_{PD1} and T_{PD2} (T_{PD1}>T_{PD2}). This quicker response time of PD1, coupled with the pre-charge functionality of M2, allows for a more efficient and controlled ramp-up of power, minimizing the risk of voltage spikes and ensuring a smoother power delivery to the modules. This setup not only stabilizes the system during high-demand scenarios but also optimizes the overall power management by aligning the speed of operation with the power requirements of the integrated circuit.

As depicted in FIG. 9, at the beginning 902 of an operation cycle, the PD signal goes low. Since PD1 operates faster than PD2, at stage 904, header M1 is OFF while header M2 is ON. This configuration initiates a pre-charge phase, where M2 alone supplies a limited current to power_local 104. This stage 904 is crucial for stabilizing the power line and preparing the circuit by gradually building up the voltage, thus minimizing the risk of voltage spikes and electrical stress. Following the pre-charge, at stage 906, when both headers M1 and M2 are turned ON, the system transitions to a full turn-on phase. During this stage 906, both headers work in conjunction to deliver the full supply voltage to power_local 104. This two-stage power control strategy ensures efficient power management, reducing the likelihood of overcurrent conditions and enhancing the reliability and longevity of the circuit.

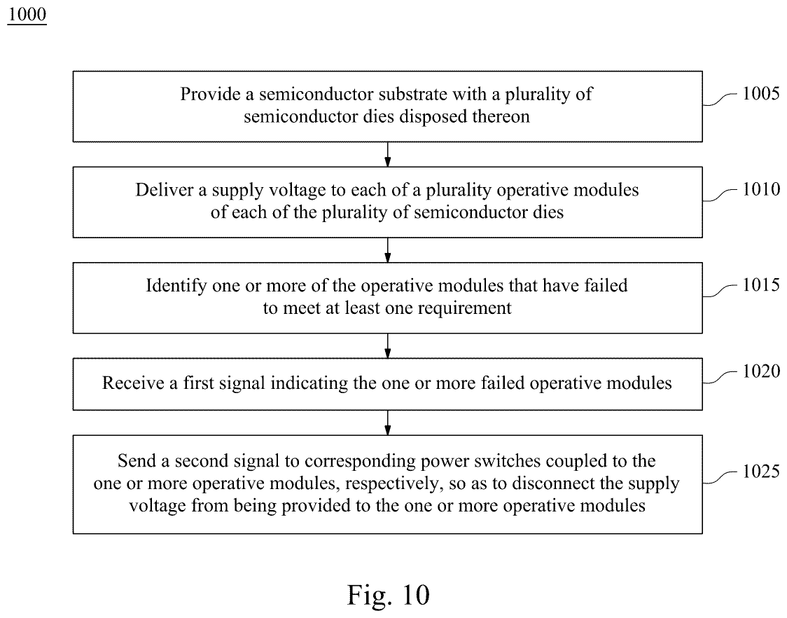

FIG. 10 illustrates an example flow chart for testing an integrated circuit, in accordance with some embodiments of the present disclosure. It is noted that the method 1000 is merely an example, and is not intended to limit the present disclosure. Accordingly, it is understood that any additional operations may be provided during, before, and after the method 1000 of FIG. 10, and that some other operations may only be briefly described herein. The method 1000 may be utilized to operate the integrated circuit 100, and thus, operations of the method 1000 will be discussed in conjunction with the components discussed in FIGS. 1-9.

As a brief overview, the method 1000 starts with operation 1002 of providing a semiconductor substrate with a plurality of semiconductor dies 100a, 100b, 100n disposed thereon. Each of the plurality of semiconductor dies 100a, 100b, 100n may comprise a plurality of operative modules 104. A plurality of power switches 102 can be coupled to the plurality of operative modules 104, respectively. In some embodiments, the plurality of semiconductor dies 100a, 100b, 100n can be disposed on a single semiconductor substrate (e.g., a wafer). In some embodiments, each of the operative modules 104 can serve as a computing unit for artificial intelligence. In some embodiments, each of the plurality of operative modules 104 may include one of the following: a natural language processing (NLP) module, a computer vision module, a speech recognition module, a recommendation system module, a predictive analytics module, an autonomous navigation module, an anomaly detection module, an emotion detection module, a generative model module, a knowledge graph module, an optical character recognition module, a data cleaning module, a dynamic pricing module, a pose estimation module, or a time series analytics module.

Corresponding to operation 1010 of FIG. 10, a supply voltage (e.g., VDD) to each of the operative modules 104 of each of the plurality of semiconductor dies 100a, 100b, 100n can be delivered. In some embodiments, the power network 110 can be disposed with respect to the plurality of semiconductor dies 100a, 100b, 100n. The power network 110 can be configured to provide a supply voltage to each of the plurality of semiconductor dies 100a, 100b, 100n. In some embodiments, the power network 110 may comprise a plurality of interconnect structures disposed in one or more metallization layers formed over the semiconductor substrate.

Corresponding to operation 1015 of FIG. 10, one or more of the operative modules that have failed to meet at least one requirement can be identified. The method for testing whether a module has failed to meet the least one requirement includes several key steps. Initially, all dies and modules within the system are activated for a comprehensive scanning test. This initial step ensures that each component is operational and ready for further diagnostics. During this phase, the current drawn by each module is closely monitored. Deviations in current levels can indicate a potential failure. Specifically, if a module's current does not meet predefined standard requirements, it is flagged as potentially faulty.

Corresponding to operation 1020 of FIG. 10, a first signal indicating the one or more failed operative modules can be received. The power control circuit 120 can be configured to receive a first signal indicating one or more operative modules of at least one of the plurality of semiconductor dies have failed.

Corresponding to operation 1025 of FIG. 10, a second signal can be sent. Based on the first signal, the power control circuit 120 can be configured to send a second signal to the corresponding power switches coupled to the one or more operative modules, respectively, so as to disconnect the supply voltage from being provided to the one or more operative modules. In some embodiments, the power control circuit 120 can function as a header decoder. The power control circuit 120 may send a signal to disable or disconnect supply voltages to corresponding power switches for a specific module on a given die. In some embodiments, the first signal may include a first number (N₁) of first data bits. The second signal may include a second number (N₂) of second data bits. In some embodiments, N₂ can be equal to 2^{N}^{₁}. In some embodiments, N₂ can be equal to a total number of the power switches formed on the semiconductor substrate.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a plurality of semiconductor dies disposed on a single semiconductor substrate, wherein each of the plurality of semiconductor dies comprises a plurality of operative modules, and a plurality of power switches coupled to the plurality of operative modules, respectively;
a power network disposed with respect to the plurality of semiconductor dies, and configured to provide a supply voltage to each of the plurality of semiconductor dies; and
a power control circuit disposed on the semiconductor substrate;
wherein the power control circuit is configured to:
receive a first signal indicating one or more operative modules of at least one of the plurality of semiconductor dies have failed; and
based on the first signal, send a second signal to the corresponding power switches coupled to the one or more operative modules, respectively, so as to disconnect the supply voltage from being provided to the one or more operative modules.

2. The integrated circuit of claim 1, wherein each of the plurality of operative modules includes one of: a natural language processing (NLP) module, a computer vision module, a speech recognition module, a recommendation system module, a predictive analytics module, an autonomous navigation module, an anomaly detection module, an emotion detection module, a generative model module, a knowledge graph module, an optical character recognition module, a data cleaning module, a dynamic pricing module, a pose estimation module, or a time series analytics module.

3. The integrated circuit of claim 1, wherein the first signal includes a first number (N₁) of first data bits, and the second signal includes a second number (N₂) of second data bits.

4. The integrated circuit of claim 3, wherein N₂ is equal to 2^{N}^{₁}.

5. The integrated circuit of claim 3, wherein N₂ is equal to a total number of the power switches formed on the semiconductor substrate.

6. The integrated circuit of claim 3, wherein the power control circuit comprises:
a plurality of first inverters, each of the plurality of first inverters configured to logically invert a corresponding one of the first data bits to provide N₁ third data bits;
a plurality of NAND gates, each of the plurality of NAND gates configured to input a corresponding pair of the third data bits to provide N₂ fourth data bits; and
a plurality of second inverters, each of the plurality of second inverters configured to logically invert a corresponding one of the fourth data bits to provide a corresponding one of the second data bits.

7. The integrated circuit of claim 1, wherein the power network comprises a plurality of interconnect structures disposed in one or more metallization layers formed over the semiconductor substrate.

8. The integrated circuit of claim 1, wherein each of the plurality of power switches includes:
a first inverter configured to receive a first data bit of the second signal and logically invert the first data bit to provide a second data bit;
a second inverter configured to receive the second data bit and logically invert the second data bit to provide a third data bit;
and a p-type transistor having a source terminal coupled to the power network, a gate terminal configured to receive the third data bit, and a drain terminal coupled to the corresponding operative module.

9. The integrated circuit of claim 1, wherein each of the plurality of power switches includes:
a first inverter configured to receive a first data bit of the second signal and logically invert the first data bit to provide a second data bit;
a second inverter configured to receive the second data bit and logically invert the second data bit to provide a third data bit;
a first p-type transistor having a source terminal coupled to the power network, a gate terminal configured to receive the third data bit, and a drain terminal; and
a second p-type transistor having a source terminal coupled to the drain terminal of the first p-type transistor, a gate terminal configured to receive a half of the supply voltage, and a drain terminal coupled to the corresponding operative module.

10. The integrated circuit of claim 1, wherein each of the plurality of power switches includes:
a first inverter configured to receive a first data bit of the second signal and logically invert the first data bit to provide a second data bit;
a second inverter configured to receive the second data bit and logically invert the second data bit to provide a third data bit;
a third inverter configured to receive the third data bit and logically invert the third data bit to provide a fourth data bit;
a fourth inverter configured to receive the fourth data bit and logically invert the fourth data bit to provide a fifth data bit;
a first p-type transistor having a source terminal coupled to the power network, a gate terminal configured to receive the fifth data bit, and a drain terminal coupled to the corresponding operative module; and
a second p-type transistor having a source terminal coupled to the power network, a gate terminal configured to receive the third date bit, and a drain terminal coupled to the corresponding operative module.

11. The integrated circuit of claim 10, wherein a size of the second p-type transistor is smaller than a size of the first p-type transistor.

12. An integrated circuit, comprising:
a plurality of semiconductor dies arranged on a single semiconductor substrate, each of the plurality of semiconductor dies comprising a plurality of operative modules, and a plurality of power switches coupled to the plurality of operative modules, respectively;
wherein at least one of the plurality of power switches is configured to selectively decouple a voltage carried through a power network from the corresponding operative module based on a first signal indicating that the corresponding operative module has failed.

13. The integrated circuit of claim 12, wherein each of the plurality of operative modules includes one of: a natural language processing (NLP) module, a computer vision module, a speech recognition module, a recommendation system module, a predictive analytics module, an autonomous navigation module, an anomaly detection module, an emotion detection module, a generative model module, a knowledge graph module, an optical character recognition module, a data cleaning module, a dynamic pricing module, a pose estimation module, or a time series analytics module.

14. The integrated circuit of claim 12, wherein the semiconductor substrate includes a wafer with a size of 100 mm, 150 mm, 200 mm, 300 mm, or 450 mm.

15. The integrated circuit of claim 12, further comprising:
a power control circuit disposed on the semiconductor substrate, wherein the power control circuit is configured to:
receive the first signal; and
based on the first signal, send a second signal to the at least one power switch, so as to disconnect the voltage from being provided to the operative module.

16. The integrated circuit of claim 12, wherein the power network comprises a plurality of interconnect structures disposed in one or more metallization layers formed over the semiconductor substrate.

17. The integrated circuit of claim 12, wherein the voltage includes a supply voltage (VDD) or a ground voltage (VSS).

18. A method for testing an integrated circuit, comprising:
providing a semiconductor substrate with a plurality of semiconductor dies disposed thereon, wherein each of the plurality of semiconductor dies comprises a plurality of operative modules, and a plurality of power switches coupled to the plurality of operative modules, respectively;
delivering a supply voltage to each of the operative modules of each of the plurality of semiconductor dies;
identifying one or more of the operative modules that have failed to meet at least one requirement;
receiving a first signal indicating the one or more failed operative modules; and
sending a second signal to the corresponding power switches coupled to the one or more operative modules, respectively, so as to disconnect the supply voltage from being provided to the one or more operative modules.

19. The method of claim 18, wherein the first signal includes a first number (N₁) of first data bits, and the second signal includes a second number (N₂) of second data bits.

20. The method of claim 18, wherein N₂ is equal to 2^{N}^{₁}, and wherein N₂ is equal to a total number of the power switches formed on the semiconductor substrate.
